(19) United States
(12) Patent Application Publication
(10) Pub. No.: US 2015/0058685 A1
(43) Pub. Date: Feb. 26, 2015

(54) METHOD AND SYSTEM OF TESTING SEMICONDUCTOR MEMORY

(71) Applicant: SAMSUNG ELECTRONICS CO., LTD., Suwon-si (KR)

(72) Inventors: UNGJIN JANG, Asan-si (KR); Kijae Song, Goyang-si (KR); Sang Kyeong Han, Seo-gu (KR)

(73) Assignee: SAMSUNG ELECTRONICS CO., LTD., Suwon-si (KR)

(21) Appl. No.: 14/293,983

(22) Filed: Jun. 2, 2014

(30) Foreign Application Priority Data
Aug. 21, 2013 (KR) 10-2013-0099172

(51) Int. Cl. G11C 29/10

(52) U.S. Cl. CPC G11C 29/10
USPC 714/719

(57) ABSTRACT

A method of testing a semiconductor memory includes generating a logical value of a test pattern through an algorithm pattern generator included in a field programmable gate array. The generated logical value is programmed in a DUT under the control of a DQ signal responding to a DQ enable signal that is generated from automatic test equipment and is then transferred to the field programmable gate array. The programmed logical value is captured from the DUT under the control the DQ signal. The generated logical value is compared with the captured logical value. Whether the DUT is defective is determined according to a result of the comparison. The DQ enable signal is applied to a time point different from a time point when a SYNC clock for synchronizing the automatic test equipment with the field programmable gate array is applied.

### CROSS-REFERENCE TO RELATED APPLICATIONS

This non-provisional U.S. Patent Application claims priority under 35 U.S.C. §119 to Korean Patent Application No. 10-2013-0099172 filed Aug. 21, 2013, in the Korean Intellectual Property Office, the disclosure of which is incorporated by reference herein in its entirety.

### TECHNICAL FIELD

Exemplary embodiments of the inventive concept relate to a method and system of testing a semiconductor memory.

### DISCUSSION OF RELATED ART

A semiconductor memory is electrically tested by programming a particular test pattern in the semiconductor memory and comparing data read from the semiconductor memory with the test pattern. Such test may be performed using automatic test equipment (simply, “ATE”).

To increase the number of semiconductor memories to be tested per unit time (referred to as UPEH), a channel connecting an ATE with a semiconductor may be split to physically copy signals.

FIG. 1 is a block diagram illustrating a system of testing a semiconductor memory according to a related art. Referring to FIG. 1, a semiconductor memory under test has Y address (ADDR) channels, Z data (DQ) channels, and X control (CTRL) channels for controlling the operation of the semiconductor memory. When X control channels, Y address channels, and Z data channels are allocated to the ATE, a splitter copies signals and distributes the copied signals to a plurality of semiconductor memories.

For channel splitting, a field programmable gate array (FPGA) may be used as a buffer.

However, since a signal output from the FPGA is synchronized with a global clock of the FPGA, timing of an output signal may be restrictively adjusted.

### SUMMARY

An exemplary embodiment of the inventive concept provides a method of testing a semiconductor memory. The method comprises generating a logical value of a test pattern through an algorithm pattern generator included in a field programmable gate array (FPGA). The generated logical value is programmed in a device-under-test (DUT) under control of a DQ signal responding to a DQ enable signal that is generated from automatic test equipment and is then transferred to the FPGA. The programmed logical value is captured from the DUT under control the DQ signal. The generated logical value is compared with the captured logical value. Whether the DUT is defective is determined according to a result of the comparison. The DQ enable signal is applied at a time point different from a time point when a SYNC clock for synchronizing the automatic test equipment with the FPGA is applied.

In an exemplary embodiment of the inventive concept, the method further comprises, after generating the logical value, generating an address signal responding to an address enable signal that is generated from the automatic test equipment and is then transferred to the FPGA.

In an exemplary embodiment of the inventive concept, the address enable signal, the DQ enable signal, and the SYNC clock are transferred to the FPGA through a channel.

In an exemplary embodiment of the inventive concept, the address enable signal and the DQ enable signal are substantially simultaneously applied.

In an exemplary embodiment of the inventive concept, the method further comprises, before generating the logical value, transferring a test program to a test memory circuit included in the FPGA from the automatic test equipment.

In an exemplary embodiment of the inventive concept, the generated logical value is generated at a rising edge of the SYNC clock.

In an exemplary embodiment of the inventive concept, the captured logical value is captured at a rising edge of the DQ enable signal.

In an exemplary embodiment of the inventive concept, when the generated logical value is consistent with the captured logical value, a first value is output. When the generated logical value is not consistent with the captured logical value, a second value is output.

In an exemplary embodiment of the inventive concept, the DQ enable signal transfers timing information for capturing the logical value received from the DUT.

An exemplary embodiment of the inventive concept provides a system of testing a semiconductor memory. The system comprises at least one field programmable gate array. The at least one field programmable gate array comprises an algorithm pattern generator configured to generate a logical value of a test pattern and a comparator configured to compare the generated logical value with a captured logical value obtained by programming the generated logical value in a device-under-test (DUT) and capturing the programmed logical value. An automatic tester generates an address enable signal, a DQ enable signal, and a SYNC clock for controlling the at least one field programmable gate array and tests whether the DUT is defective according to a result of the comparison. The address enable signal and the DQ enable signal are applied at a time point different from a time point when the SYNC clock is applied.

In an exemplary embodiment of the inventive concept, each of the address enable signal, the DQ enable signal, and the SYNC clock is transferred through a channel to the at least one field programmable gate array.

In an exemplary embodiment of the inventive concept, the captured logical value is captured at a rising edge of the DQ enable signal.

In an exemplary embodiment of the inventive concept, the DQ enable signal transfers timing information for capturing the logical value received from the DUT.

In an exemplary embodiment of the inventive concept, the comparator outputs a first value when the generated logical value is consistent with the captured logical value and outputs a second value when the generated logical value is not consistent with the captured logical value.

In an exemplary embodiment of the inventive concept, the field programmable gate array stores the generated logical value or the captured logical value.

According to an exemplary embodiment of the inventive concept, there is provided a method of testing a semiconductor memory. In the method, a logical value of a test pattern is generated by a field programmable gate array (FPGA). The generated logical value is programmed in a device-under-test (DUT) under the control of a DQ signal responding to a DQ enable signal. The DC signal is generated from an automatic test equipment (ATE) and transferred to the FPGA. The programmed logical value is captured from the DUT under the control the DQ signal. The generated logical value is compared with the captured logical value, and whether the DUT is defective is determined according to a result of the comparison. A time when the DQ enable signal is applied to the FPGA is not related with a SYNC clock for synchronizing the automatic test equipment with the FPGA.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a block diagram illustrating a semiconductor memory test system using a general channel splitting method according to a related art;

FIG. 2 is a block diagram illustrating a semiconductor memory test system according to an exemplary embodiment of the inventive concept;

FIG. 3 is a timing diagram illustrating output signals when a logical value of a test pattern is programmed in a DUT, according to an exemplary embodiment of the inventive concept;

FIG. 4 is a timing diagram illustrating output signals when a logical value programmed in DUT is read, according to an exemplary embodiment of the inventive concept;

FIG. 5 is a flow chart illustrating a semiconductor memory test method according to an exemplary embodiment of the inventive concept;

FIG. 6 is a block diagram illustrating a semiconductor memory test system according to an exemplary embodiment of the inventive concept;

FIG. 7 is a diagram showing the number of semiconductor memories tested at the same time according to an applied technique;

FIG. 8 is a timing diagram illustrating output signals when a logical value of a test pattern is programmed in a device under test (DUT), according to an exemplary embodiment of the inventive concept; and

FIG. 9 is a timing diagram illustrating output signals when a programmed logical value is read from a device under test (DUT), according to an exemplary embodiment of the inventive concept.

### DETAILED DESCRIPTION OF EMBODIMENTS

Exemplary embodiments will be described in detail with reference to the accompanying drawings. The inventive concept, however, may be embodied in various different forms, and should not be construed as being limited only to the illustrated embodiments. As used herein, the singular forms “a”, “an” and “the” are intended to include the plural forms as well, unless the context clearly indicates otherwise.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present.

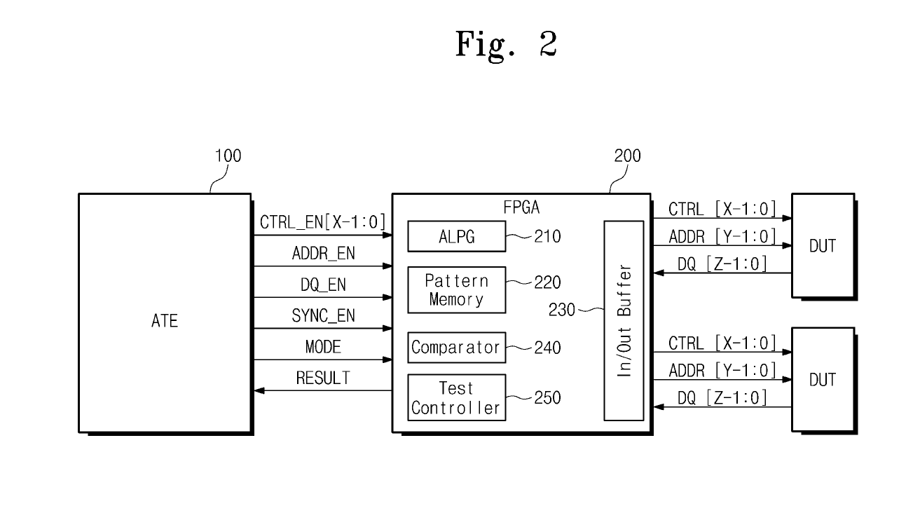

FIG. 2 is a block diagram illustrating a semiconductor memory test system according to an exemplary embodiment of the inventive concept.

Referring to FIG. 2, a semiconductor memory test system according to an exemplary embodiment of the inventive concept comprises an automatic test equipment (hereinafter, referred to as ATE) 100 and a field programmable gate array (hereinafter, referred to as FPGA) 200.

The ATE 100 is connected to the FPGA 200 through a plurality of channels. The ATE 100 controls output signal timing of a logical value generated by the FPGA 200.

The FPGA 200 comprises an algorithm pattern generator 210, a pattern memory circuit 220, an input/output buffer 230, a comparator 240, and a test controller 250.

The ATE 100 generates a test program on a waveform to be applied to a device-under-test (DUT). The test program, for example, may comprise a DC test, AC test, a function test and the like. For example, the DUT is tested by programming a signal generated according to the test program of the ATE 100 in the DUT and comparing data read from the DUT with an expected pattern.

The algorithm pattern generator 210 is a circuit configured to calculate a logical value of a test pattern. Data to be programmed in the DUT is formed as a test pattern and is stored in the pattern memory circuit 220 of the FPGA 200. The algorithm pattern generator 210 sequentially generates a logical value using a test pattern stored in the pattern memory circuit 220. The logical value calculated is data to be programmed in the DUT, for example, hexadecimal data. However, exemplary embodiments of the inventive concept are not limited thereto.

The input/output buffer 230 programs a logical value calculated by the algorithm pattern generator 210 in the DUT or captures data read from the DUT.

The comparator 240 compares the data captured by the input/output buffer 230 with the test pattern calculated by the algorithm pattern generator 210. When the data captured by the input/output buffer 250 is identical to the test pattern calculated by the algorithm pattern generator 210, the comparator 240 outputs a predetermined value (e.g., ‘1’) to the ATE 100. When the data captured by the input/output buffer 250 is different from the test pattern calculated by the algorithm pattern generator 210, the comparator 240 outputs a predetermined value (e.g., ‘0’) to the ATE 100, determining whether the DUT is defective.

The test controller 250 enables the FPGA 200 to communicate with the ATE 100 or controls operations of internal circuits of the FPGA 200.

The ATE 100 outputs a signal associated with timing and a control signal associated with an operation of the FPGA 200. Although not shown in FIG. 2, the ATE 100 may be configured to supply power for driving of an overall system.

Signals CTRL_EN, ADDR_EN and DQ_EN transfer timing when logical values on signals CTRL, ADDR and DQ calculated by the FPGA 200 are output to the input/output buffer 230.

The signal CTRL operates the DUT in response to the signal CTRL_EN from the ATE 100. The signal CTRL may comprise a RAS indicating a row address of the DUT being a semiconductor memory, a CAS indicating a column address, and a clock enable signal CKE. The number of channels required to connect the ATE 100 with the FPGA 200 corresponds to the number of signals (e.g., including RAS, CAS, CKE, ZQ, etc.) included in the signal CTRL. When some signals are output substantially at the same time, the number of channels may be reduced.

When the signals ADDR_EN and DQ_EN are applied to the FPGA 200 from the ATE 100, for programming, the FPGA 200 applies the signal ADDR and the signal DQ to the DUT through a corresponding address. Since the signals ADDR_EN and DQ_EN are provided to the FPGA 200 at the same timing, the number of channels is reduced.

A signal SYNC_CLK is a clock signal for synchronization with a clock where the ATE 100 and the FPGA 200 operate. When the ATE 100 and the FPGA 200 are synchronized with each other, a logical value of a test pattern is generated at a rising edge time point of the signal SYNC_CLK synchronized.

When a signal MODE has a value of ‘0’, the FPGA 200 is provided with a test program from the ATE 100 for calculation of the algorithm pattern generator 210 and stores the test program in the pattern memory circuit 220 in a test pattern form. When the signal MODE has a value of ‘1’, the ATE 100 and the FPGA 200 are synchronized with each other, thus generating timing information and a logical value of a test pattern. A memory may be tested.

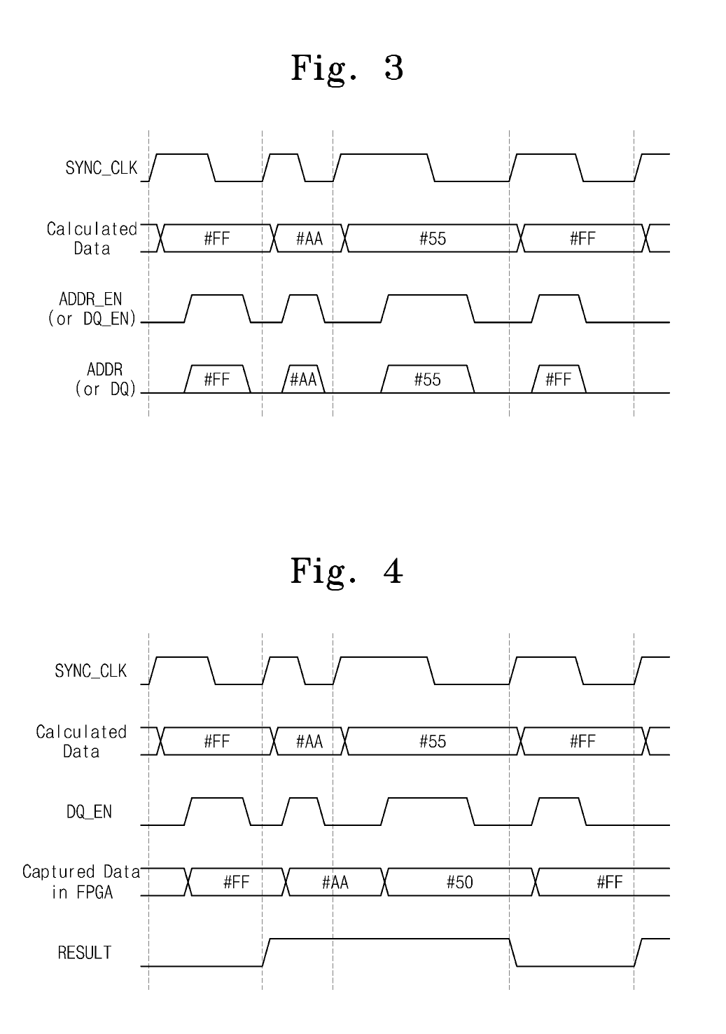

FIG. 3 is a timing diagram illustrating output signals when a logical value of a test pattern is programmed in a DUT, according to an exemplary embodiment of the inventive concept.

Referring to FIG. 3, a time on the fly (TOF) characteristic of a DUT or an asynchronous semiconductor memory is tested by controlling a FPGA 200 under a condition where a signal SYNC_CLK is varied every period. As shown in FIG. 3, the TOF characteristic is tested while a frequency of the signal SYNC_CLK is varied every period. For example, the FPGA 200 is used as a buffer for signal splitting. In this case, when the TOP characteristic is tested with a global clock of a system being frequently varied, a response speed is lowered. For example, test efficiency is lowered. However, according to an exemplary embodiment of the inventive concept, a global clock of a system is controlled by the ATE 100 with performance higher than performance of the FPGA 200. Thus, the efficiency of a TOF test can be increased.

Calculated data is generated from an algorithm pattern generator 210 of the FPGA 200. For example, the calculated data is generated at every rising edge of a signal SYNC_CLK.

For example, when the FPGA 200 is used as a buffer for signal splitting, signals ADDR_EN and DQ_EN are synchronized with a global clock SYNC_CLK of a system. Thus, output timing might not be adjusted. However, according to an exemplary embodiment of the inventive concept, output timings of signals ADDR and DQ are controlled by controlling timings of signals ADDR_EN and DQ_EN. Thus, a test operation of checking an AC parameter characteristic of DUT may be performed.

FIG. 4 is a timing diagram illustrating output signals when a logical value programmed in a DUT is read, according to an exemplary embodiment of the inventive concept.

Referring to FIG. 4, an ATE 100 activates a signal DQ by freely controlling a timing when a signal DQ_EN is applied, regardless of a signal SYNC_CLK. During a read operation, as a signal DQ_EN is applied to a FPGA 200, a signal DQ is applied to a device-under-test (DUT) from the FPGA 200. An input/output buffer 230 captures data received from the DUT. For example, an operation of capturing a programmed logical value is performed every rising edge of a signal DQ_EN.

After an operation of capturing the programmed logical value is performed, comparison is executed to determine whether the DUT is defective. Such data comparison is performed at a next rising edge of the signal SYNC CLK. In FIG. 4, calculated logical values #FF and #AA are identical to logical values captured by the FPGA 200. In this case, the FPGA 200 determines the DUT to be normal. Thus, the FPGA 200 outputs data ‘1’. Referring to a third period of FIG. 4, in the case of a calculated logical value #55, a logical value is likewise captured at a third rising edge of the signal DQ_EN. Data comparison is executed at a fourth rising edge of the signal SYNC_CLK. In FIG. 4, the captured data is #50 and is different from a calculated logical value #55. Thus, the FPGA 200 determines the DUT to be defective. Therefore, the FPGA 200 outputs data ‘0’.

Like a logical value is programmed, when a programmed logical value is read, the ATE 100 checks an AC parameter characteristic of the DUT by freely controlling timing of the signal DQ_EN.

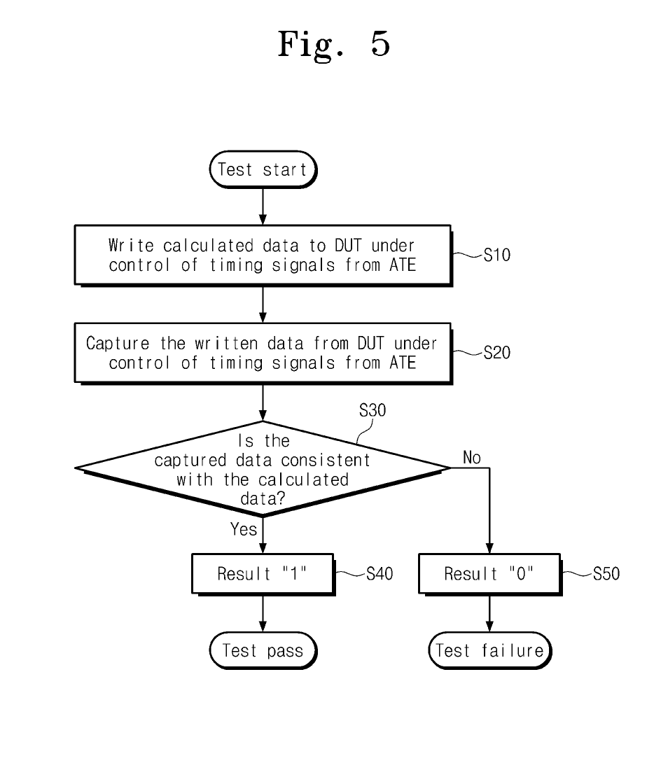

FIG. 5 is a flow chart illustrating a semiconductor memory test method according to an exemplary embodiment of the inventive concept.

Referring to FIGS. 2 and 5, when a DUT is tested, a program step is executed. In step S10, calculated data of a test pattern calculated by an algorithm pattern generator 210 of a FPGA 200 is stored in an input/output buffer 230, and is programmed in the DUT according to timing signals generated from an ATE 100. The timing signals may include signals CTRL_EN, ADDR_EN,

DQ_EN, and SYNC_EN.

When the DUT is programmed, the written data is captured (S20). According to timing signals generated from the ATE 100, a logical value programmed is read from the DUT and is captured by the input/output buffer 230. Data may be captured in substantially the same manner as described above.

In step S30, a comparator 240 determines whether the captured data is consistent with the calculated data. When the captured data is consistent with the calculated data, the ATE 100 outputs ‘1’ indicating that a test succeeds (S40). When the captured data is not consistent with the calculated data, the ATE 100 outputs ‘0’ indicating that a test fails.

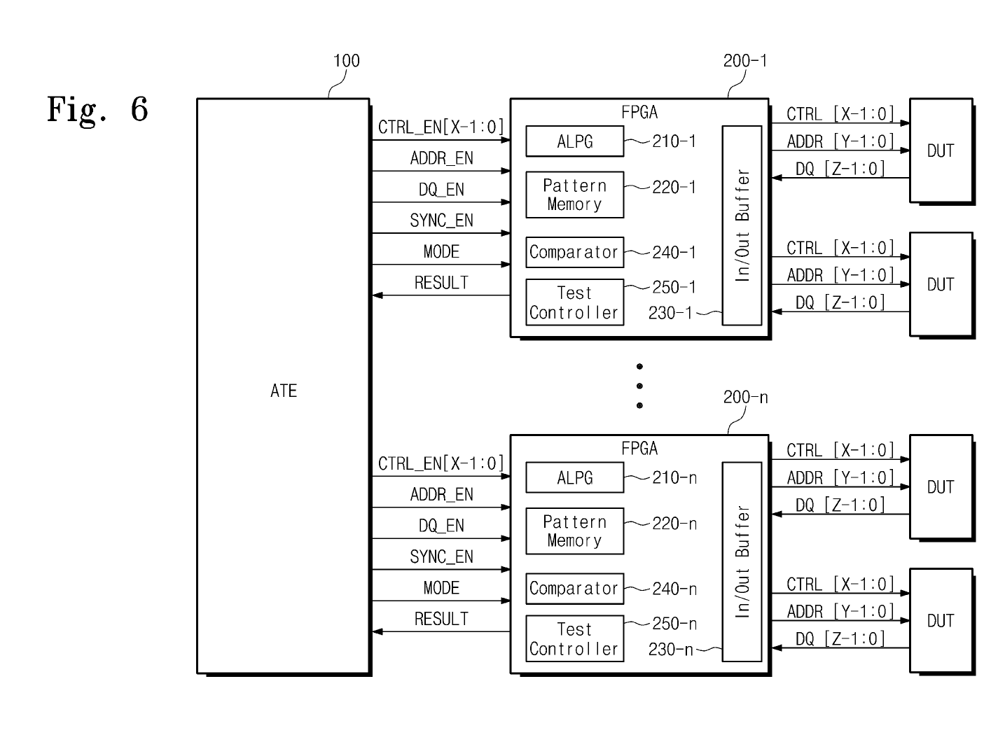

FIG. 6 is a block diagram illustrating a semiconductor memory test system according to an exemplary embodiment of the inventive concept. In an exemplary embodiment of the inventive concept, n FPGAs 200-1 to 200-n are connected to an ATE 100 and two devices under test (DUTs) are connected to a FPGA 200-1. However, exemplary embodiments of the inventive concept are not limited thereto. Alternatively, three or more DUTs may be connected to one FPGA.

The number of DUTs to be tested at the same time is increased by increasing the number of FPGAs connected to one ATE 100.

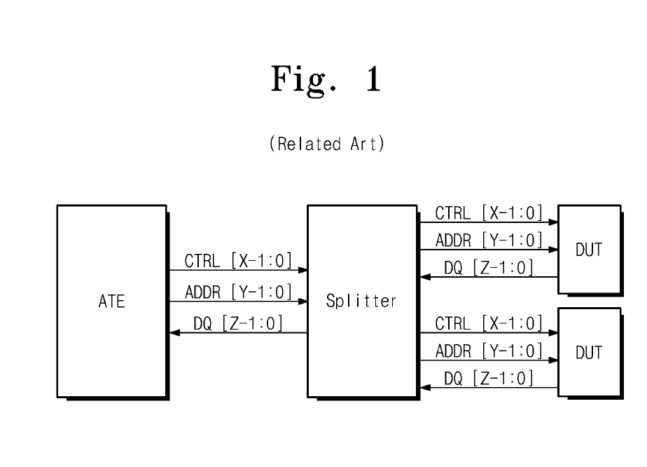

When a FPGA is used as a buffer for signal splitting, as illustrated in FIG. 1, X control signals, Y address signals, and Z DQ signals are allocated. Thus, the number of FPGAs connected to one ATE is restricted. However, a FPGA generates signals ADDR and DQ, and an ATE generates enable signals for activating the signals ADDR and DQ. Thus, one channel is required. Since other FPGAs are connected to remaining channels for a simultaneous test, UPEH (Unit Per Equipment Hour) may be increased.

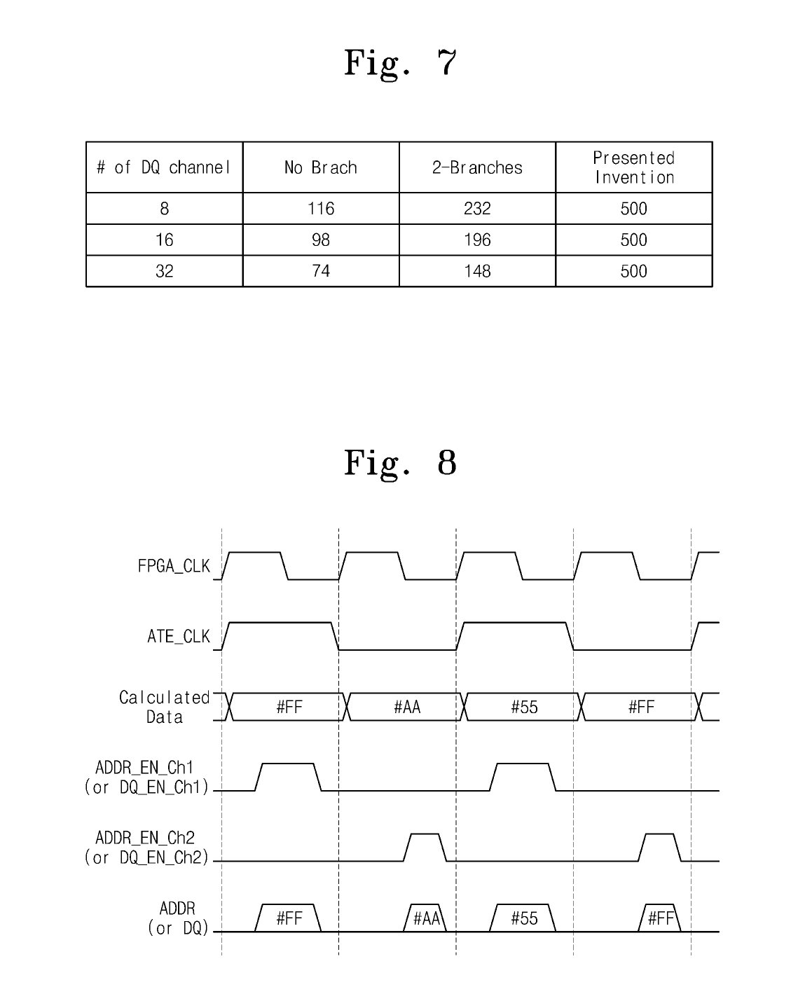

FIG. 7 is a diagram showing the number of semiconductor memories tested at the same time according to an applied technique. Referring to FIG. 7, for the purpose of description, an ATE has 5000 channels, a FPGA is connected to two devices under test (DUTs), and the number of signals CTRL is 15, and the number of signals ADDR is 20. A test operation is performed under the condition where the number of signals DQ is variable to, for example, 8, 16, are 32. When a FPGA is used as a buffer without branch, the number of DUTs to be tested at the same time is 116 (5000/(15+20+8)).

When a FPGA is simply used as a buffer for signal splitting, the number of channels connected between an ATE and a FPGA is not varied. However, since two DUTs are connected to a FPGA, the number of DUTs to be tested at the same time is about two times more than when no splitting is made. For example, the number of DUTs to be tested at the same time may be 232.

A test method according to an exemplary embodiment of the inventive concept may contain 15 channels for signal CTRL and channels respectively corresponding to signals ADDR_EN, DQ_EN, SYNC_EN and MODE and RESULT for outputting a comparison result. Thus, the number of DUTs to be tested at the same time is 500 (=5000/(15+1+1+1+1+1)*2). Also, although a DQ channel may be further included, a channel for a signal DQ_EN may be included. Thus, a multi-channel memory device may be efficiently tested.

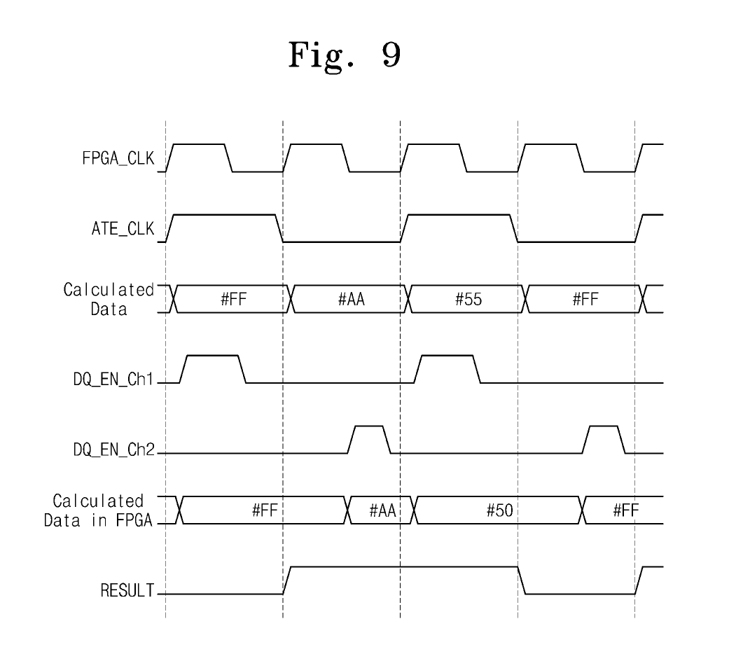

An exemplary embodiment of the inventive concept allows for increased in test speed using low-performance and old-fashioned ATE and FPGA. For example, an embodiment where a test operation is performed using an ATE 100 operating at 500 MHz and a FPGA 200 operating at 1 GHz is described below with reference to FIGS. 8 and 9.

FIG. 8 is a timing diagram illustrating output signals when a logical value of a test pattern is programmed in a device under test (DUT), according to an exemplary embodiment of the inventive concept.

Referring to FIGS. 2 and 8, calculated data is generated by an algorithm pattern generator 210 of a FPGA 200 at every rising edge of a signal SYNC CLK. Since a logical value is generated by the FPGA 200, data is generated in synchronization with a clock of the FPGA 200. Among channels connecting the ATE 100 with the FPGA 200, two channels are allocated for each of signals ADDR_EN and DQ_EN because enable signals are output in synchronization with a clock of the ATE 100 and the FPGA 200 has twice as much operation speed as the ATE 100. Referring to FIG. 8, the signal ADDR_EN (or, DQ_EN) is applied through a channel 1, and the signal ADDR_EN (or, DQ_EN) is applied through a channel 2 during a next period. The FPGA 200 applies signals ADDR and DQ to the DUT in response to a command of an active signal, performing a program operation. For example, a program speed is about twice higher than when the DUT is programmed only using an ATE 100.

FIG. 9 is a timing diagram illustrating output signals when a programmed logical value is read from a device under test (DUT), according to another embodiment of the inventive concepts.

When a command is received through two DQ_EN signal channels, a programmed logical value is captured at a rising edge of each enable signal. A calculated logical value is compared with a captured logical value at a rising edge of a next clock of the FPGA. When the calculated logical value is consistent with the captured logical value, data ‘1’ is output. When the calculated logical value is not consistent with the captured logical value, data ‘0’ is output. A capture speed is doubled as compared with when a capture operation is performed on a DUT only using the ATE 100. Thus, an overall test speed is doubled. Substantially the same programming, capturing and comparing operations as those described above may be performed.

According to an exemplary embodiment of the inventive concept, various test operations (e.g., a TOF test operation, an AC parameter test operation, etc.) are executed by removing a timing restriction due to the use of the FPGA 200. As the number of channels connecting an ATE 100 with a FPGA 200 is reduced, more FPGAs are connected to the ATE 100. Thus, the number of semiconductor memories to be tested is increased. Also, a test speed is increased using low-performance and old-fashioned ATE and FPGA as compared with when an ATE 100 is only used.

While the inventive concept has been described with reference to exemplary embodiments thereof, it will be apparent to those skilled in the art that various changes in form and detail may be made thereto without departing from the spirit and scope of the present invention defined by the following claims.

1. A method of testing a semiconductor memory, the method comprising:
generating a logical value of a test pattern through an algorithm pattern generator included in a field programmable gate array (FPGA);
programming the generated logical value in a device-under-test (DUT) under control of a DQ signal responding to a DQ enable signal that is generated from an automatic test equipment and is then transferred to the FPGA;
capturing the programmed logical value from the DUT under control of the DQ signal; and
comparing the generated logical value with the captured logical value and determining whether the DUT is defective according to a result of the comparison,
wherein the DQ enable signal is applied at a time point different from a time point when a SYNC clock for synchronizing the automatic test equipment with the FPGA is applied.

2. The method of claim 1, further comprising:
after generating the logical value, generating an address signal in response to an address enable signal that is generated from the automatic test equipment and is then transferred to the FPGA.

3. The method of claim 2, wherein the address enable signal, the DQ enable signal, and the SYNC clock are transferred to the FPGA through a channel.

4. The method of claim 2, wherein the address enable signal and the DQ enable signal are substantially simultaneously applied.

5. The method of claim 1, further comprising:
before generating the logical value, transferring a test program to a test memory circuit included in the FPGA from the automatic test equipment.

6. The method of claim 1, wherein the generated logical value is generated at a rising edge of the SYNC clock.

7. The method of claim 1, wherein the captured logical value is captured at a rising edge of the DQ enable signal.

8. The method of claim 1, further comprising:
when the generated logical value is consistent with the captured logical value, outputting a first value; and
when the generated logical value is not consistent with the captured logical value, outputting a second value.

9. The method of claim 1, wherein the DQ enable signal transfers timing information for capturing the logical value received from the DUT.

10-15. (canceled)

16. A method of testing a semiconductor memory, the method comprising:
generating a logical value of a test pattern by a field programmable gate array (FPGA);
programming the generated logical value in a device-under-test (DUT) under control of a DQ signal responding to a DQ enable signal, the DC signal generated from an automatic test equipment (ATE) and transferred to the FPGA;
capturing the programmed logical value from the DUT under control of the DQ signal; and
comparing the generated logical value with the captured logical value and determining whether the DUT is defective according to a result of the comparison,
wherein a time when the DQ enable signal is applied to the FPGA is not related with a SYNC clock for synchronizing the automatic test equipment with the FPGA.
